(19) United States
(12) Patent Application Publication
(10) Pub. No.: US 2007/0164411 A1
(43) Pub. Date: Jul. 19, 2007

(54) Semiconductor package structure and fabrication method thereof

(75) Inventors: Chien-Ping Huang, Hsinchu Hsein (TW); Chin-Huang Chang, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/603,687

(22) Filed: Nov. 21, 2006

(30) Foreign Application Priority Data
Jan. 16, 2006 (TW) 095101562

(51) Int. Cl. H01L 23/02

(52) U.S. Cl. 257/678

(57) ABSTRACT

A semiconductor package structure and a fabrication method thereof are provided. The fabrication method includes providing a semiconductor chip having an active surface, a inactive surface, and a plurality of bond pads formed on the active surface; coupling one or more substrates to the active surface in such a way that the bond pads are exposed through one or more openings in the one or more substrates and/or gaps between the substrates to electrically connect the bond pads to the substrate; attaching and electrically connecting the semiconductor chip to a leadframe having a plurality of leads; and encapsulating the semiconductor chip, the substrate, and the leadframe with an encapsulant, with at least bottom surfaces of the leads of the leadframe being exposed from the encapsulant. An indented structure is therefore formed on the bottom surface of an inner portion of each of the leads of the leadframe.

### FIELD OF THE INVENTION

The present invention relates to semiconductor packages and fabricating methods thereof, and, more particularly, to a leadframe based semiconductor package and a fabricating method thereof.

### BACKGROUND OF THE INVENTION

Conventionally, a thin small outline package (TSOP) is formed by attaching a semiconductor chip to a leadframe having a plurality of leads on its two opposing sides and then forming an encapsulant to encapsulate the semiconductor chip, allowing the chip to be electrically connected to an external device via the leads of the leadframe.

A perspective view of a conventional TSOP is shown in FIG. 1. The TSOP shown in FIG. 1 comprises a leadframe 11 having a die pad 111 and a plurality of leads 112 disposed along two opposing sides of the die pad 111; a semiconductor chip 10 electrically connected to the leads 112 via a plurality of bonding wires 12; and an encapsulant 13 for encapsulating the chip 10, bonding wires 12, and the leadframe 11, except a portion of each of the leads 112 intended for being exposed from the encapsulant 13. The semiconductor chip 10 is electrically connected to an external device via the exposed portions of the leads 112.

In order to improve the electrical connection between the semiconductor chip and the leads, so as to obtain better electrical performance and increased functionality, a semiconductor package disclosed by U.S. Pat. No. 5,780,925 is proposed of which the semiconductor chip is attached to the leads to form a Chip on Lead TSOP (COL TSOP). As shown in FIG. 2, the leadframe 21 has no die pad and comprises a plurality of long leads 211 and short leads 212 abreast with each other. The chip 20 is attached to the long leads 211 and electrically connected to both the long leads 211 and the short leads 212 via the bonding wires 22. Then an encapsulant 23 is formed to encapsulate the chip 20, bonding wires 22, and the inner portions of the long and short leads 211, 212.

One problem with the foregoing semiconductor package is that the leads must protrude from the encapsulant to be able to electrically connect the package to an external device such as a printed circuit board, and this will occupy a large area of the printed circuit board.

In order to solve this problem, U.S. Pat. Nos. 5,363,279, 6,030,858 and 6,399,420 disclose a bottom lead package (BLP) in which the bottom surfaces of the leads are exposed. As shown in FIG. 3, the semiconductor package disclosed by U.S. Pat. No. 5,363,279 is provided, in which a leadframe 31 has two rows of leads 311 abreast from each other. Each lead 311 has an inner portion 311a and an outer portion 311b. The outer portion 311b is bent downward from the inner portion 311a, allowing the semiconductor chip 30 having a plurality of bond pads 300 on the active surface thereof to be attached to the inner portion 311a of the leads 311. At the same time an encapsulant 33 is formed to encapuslant the semiconductor chip 30, bonding wires 32 and the leadframe 31, allowing the outer portion 311b of the lead 311 to be exposed and electrically connected to a printed circuit board.

However, this type of package structure is only suitable for semiconductor chips that have bond pads concentrated at the center, whereas it is not that suitable for cross-type, I-type arrangement, or the mixture of cross-type and I-type pad arrangements.

In addition, as shown in FIG. 4, U.S. Pat. No. 6,630,729 discloses a Dual Flat No Lead (DFN) package, wherein a semiconductor chip 40 is attached to a leadframe having a plurality of leads 411 and electrically connected to the leads 411 via bonding wires 42, allowing the top and bottom surfaces of the leads 411 to be exposed from the encapsulant 43. In this configuration, the leads 411 protruding from the bottom of the encapsulant allow an upper semiconductor package can be electrically connected to the leads 411 protruding from the top of the encapsulant of a lower semiconductor package. However, this type of package cannot be used for semiconductor chips that have pads arranged at the center, or in cross-type or I-type arrangements such as DRAM chip.

Additionally, the different types of semiconductor packages described above are all not suitable for disposing passive components, thereby limiting the ability for the package to enhance the electronic performance through use of such components.

Thus, there is an urgent need for developing a semiconductor package that can accommodate different types of arrangements of bond pads on the active surface of the semiconductor chip, as well as passive components in the package in order to increase the electrical performance.

### SUMMARY OF THE INVENTION

In accordance with the foregoing drawbacks of the conventional technology, a primary objective of the present invention is to provide a semiconductor package and fabricating method thereof that are suitable for accommodating semiconductor chips with different bond pad arrangements.

Another objective of the invention is to provide and a semiconductor package and fabricating method thereof with no outer leads that is thin and compact in structure.

Further, another objective of the invention is to provide a semiconductor package and fabricating method thereof in which passive components can be accommodated so as to increase the electrical performance.

In order to achieve the foregoing and other objectives, the semiconductor package of the invention comprises: a semiconductor chip having an active surface whereon a plurality of bonding pads are disposed and an opposing non-active surface; a substrate attached on the active surface in a way that the bonding pads are exposed via one or more openings; bonding wires for electrically connecting the bond pads of the semiconductor chip and the substrate; a leadframe having a plurality of leads whereon the semiconductor chip is accommodated and electrically connected thereto; and an encapsulant for encapsulating the semiconductor chip, substrate, and the leadframe, wherein at least the bottom surfaces of the leads of the leadframe are exposed from the encapsulant. An indented structure is formed on the bottom surface of an inner portion of each of the leads of the leadframe so that the leads can be effectively engaged with the encapsulant.

The fabricating method of the semiconductor package of the invention, comprises: preparing a semiconductor chip having an active surface whereon a plurality of bond pads are formed and an opposing non-active surface, the semiconductor chip being attached to a substrate via its active surface in such a way that the bond pads on the active surface are exposed to be electrically connected with the substrate; attaching the semiconductor chip that has been coupled to a substrate to a leadframe having a plurality of leads and electrically connecting the semiconductor chip to the leadframe; and forming an encapsulant to encapsulate the semiconductor chip, substrate, and leadframe, wherein the bottom surfaces of the leads are exposed from the leadframe. An indented structure is formed on the bottom surface of an inner portion of each of the leads of the leadframe so that the leads can be effectively engaged with the encapsulant.

In other preferred embodiments, the substrate attached on the active surface of the semiconductor chip is formed with an opening to expose the bond pads of the semiconductor chip so that the bond pads can be electrically connected to the substrate via bonding wires; the size of the substrate can be larger, smaller, or equal in size with the semiconductor chip; the substrate is electrically connected to the leads of the leadframe via bonding wires of via other conductive materials such as solder balls; the leads of the leadframe are arranged on two sides of the leadframe, allowing the semiconductor chip coupled with a substrate to be attached to the leads via the chip or the substrate; and, in addition, a die pad can be provided at the center of the leadframe so as to directly attach the semiconductor chip to the die pad or attach the semiconductor chip to the die pad and the leads. In addition, another semiconductor chip can be attached to the indented structure on the bottom surface of the inner portion of the leads, allowing a plurality of semiconductor chips to be accommodated and electrically connected within the semiconductor package. Moreover, the semiconductor chip coupled with a substrate can be attached to the leadframe via the non-active surface or one side of the leadframe, and electrically connected to the leadframe via bonding wires or conductive materials such as solder balls. Also, the active surface of the semiconductor chip can have a plurality of substrates whose sizes are smaller than the chip disposed thereon, and the substrates are arranged on the chip in such a way that the bond pads disposed on the active surface of the semiconductor chip can be electrically connected to those substrates via bonding wires.

Thus, according to the semiconductor package structure of the invention and the fabricating method thereof, the design and method basically involve forming an opening in advance on the substrate at a position based on the arrangement of the bond pads of the semiconductor chip, so that when the substrate is attached to the active surface of the semiconductor chip, the bond pads on the active surface are exposed from the opening, or, alternatively, a plurality of substrates are arranged on the active surface of the semiconductor chip in such a way that the bond pads are exposed so as to permit electrical connection between the bond pads of the semiconductor chip and the substrates. Then, the substrates are electrically connected to a leadframe having a plurality of leads, followed by the formation of an encapsulant for encapsulating the substrates, semiconductor chip, and the leadframe, wherein the bottom surfaces of the leads are exposed from the encapsulant, thus providing electrical connection for the package to an external device, such that a compact and thin package without extended leads is formed which can be used in semiconductor chips having different bond pad arrangement.

Moreover, in the semiconductor package of the invention, passive components can also be included by attachment to the substrate, so as to improve the overall electrical functionality and performance of the package.

In comparison with the conventional technology, the semiconductor package of the invention and the fabricating method thereof can be used in packaging semiconductor chip with different bond pad arrangements, and is compact and thin in structure without the extended leads. Moreover, the package can be easily stacked on top of another package, and, furthermore, the electrical functionality can be improved by including passive components within the package.

### BRIEF DESCRIPTION OF THE DRAWINGS

The present invention can be more fully understood by reading the following detailed description of the preferred embodiments, with reference made to the accompanying drawings, wherein:

FIG. 1 is a perspective view of a conventional Thin Small Outline Package (TSOP);

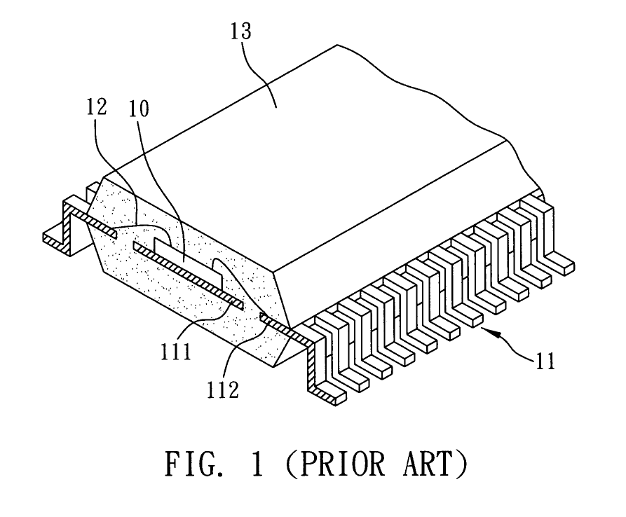

FIG. 2 is a cross-sectional view of a Chip on Lead Thin Small Outline Package (COL TSOP);

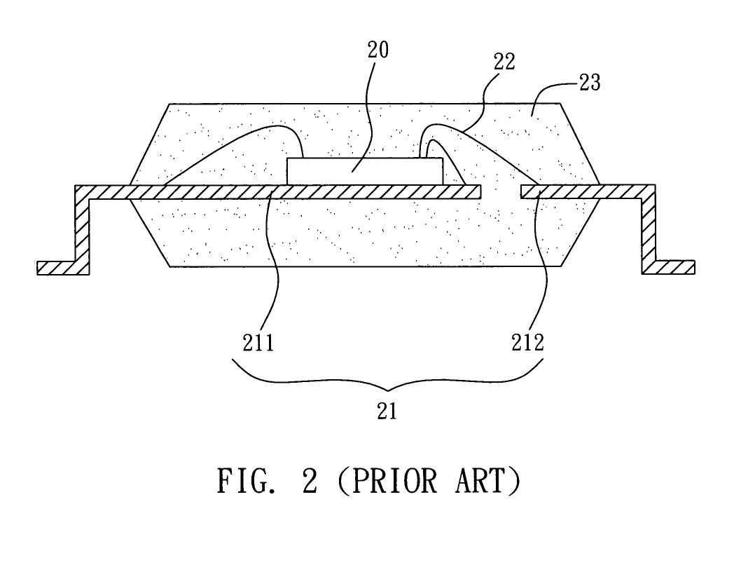

FIG. 3 is a cross-sectional view of a semiconductor package disclosed by U.S. Pat. No. 5,363,279;

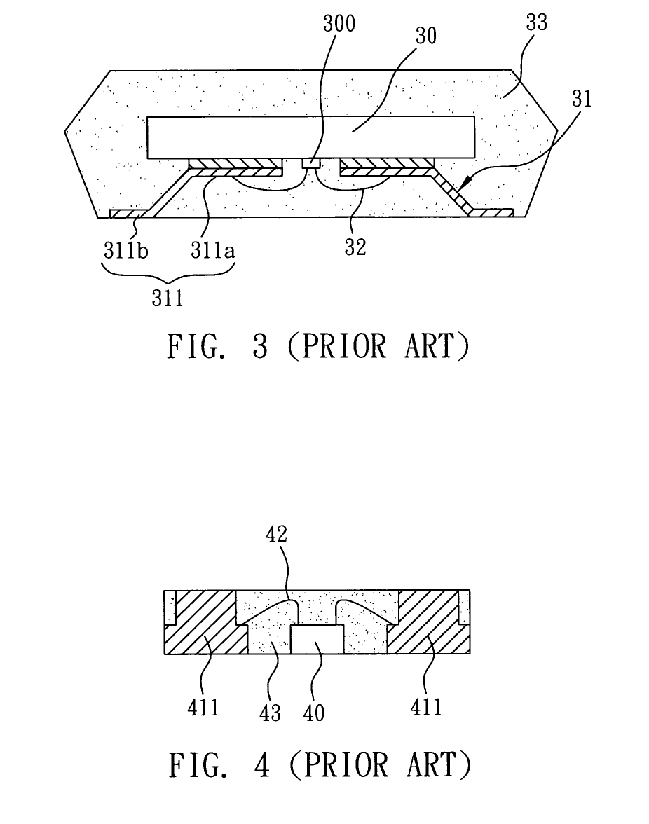

FIG. 4 is a cross-sectional view of a Dual Flat No Lead (DFN) package disclosed by U.S. Pat. No. 6,630,729;

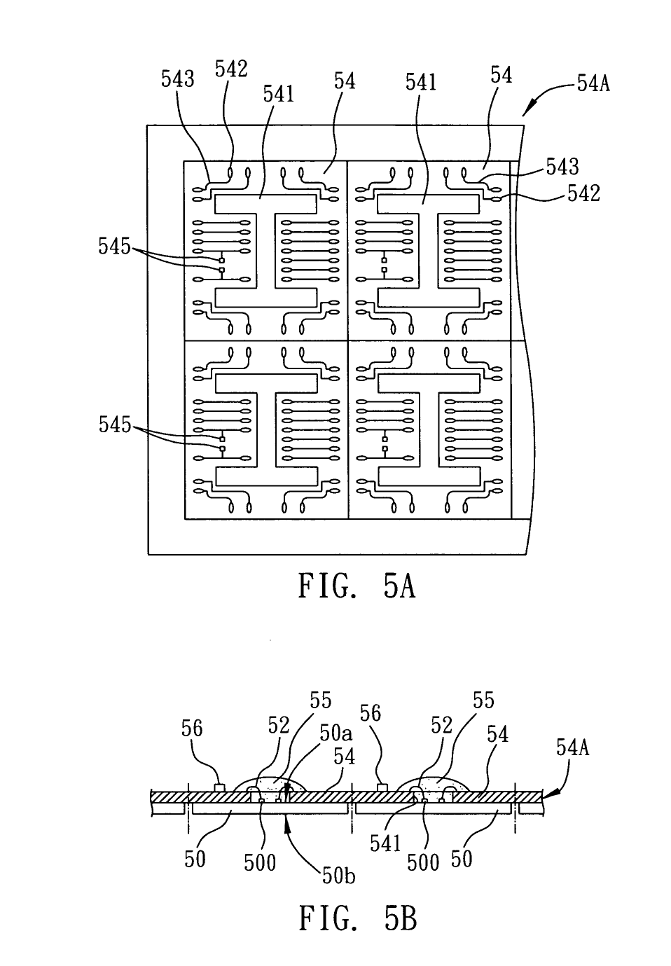

FIG. 5A and FIGS. 5B to 5F are, respectively, a top view and cross-sectional views showing the fabricating method of the semiconductor package in accordance with the first preferred embodiment of the present invention;

FIGS. 6A to 6D are cross-sectional views showing the fabricating method of the semiconductor package in accordance with the second preferred embodiment of the invention;

FIG. 7 is a cross-sectional view showing the semiconductor package of the third preferred embodiment of the invention;

FIG. 8 is a cross-sectional view showing the semiconductor package of the fourth preferred embodiment of the invention;

FIGS. 9A to 9D are cross-sectional views showing the fabricating method of the semiconductor package of the fifth preferred embodiment of the invention.

FIG. 10A and 10B are cross-sectional views showing the semiconductor package of the sixth preferred embodiment of the invention;

FIGS. 11 is a cross-sectional view showing the semiconductor package of the seventh preferred embodiment of the invention;

FIGS. 12 is a cross-sectional view showing the semiconductor package of the eighth preferred embodiment of the invention;

FIGS. 13A and 13D are cross-sectional views showing the semiconductor package of the ninth preferred embodiment of the invention.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

### First Preferred Embodiment

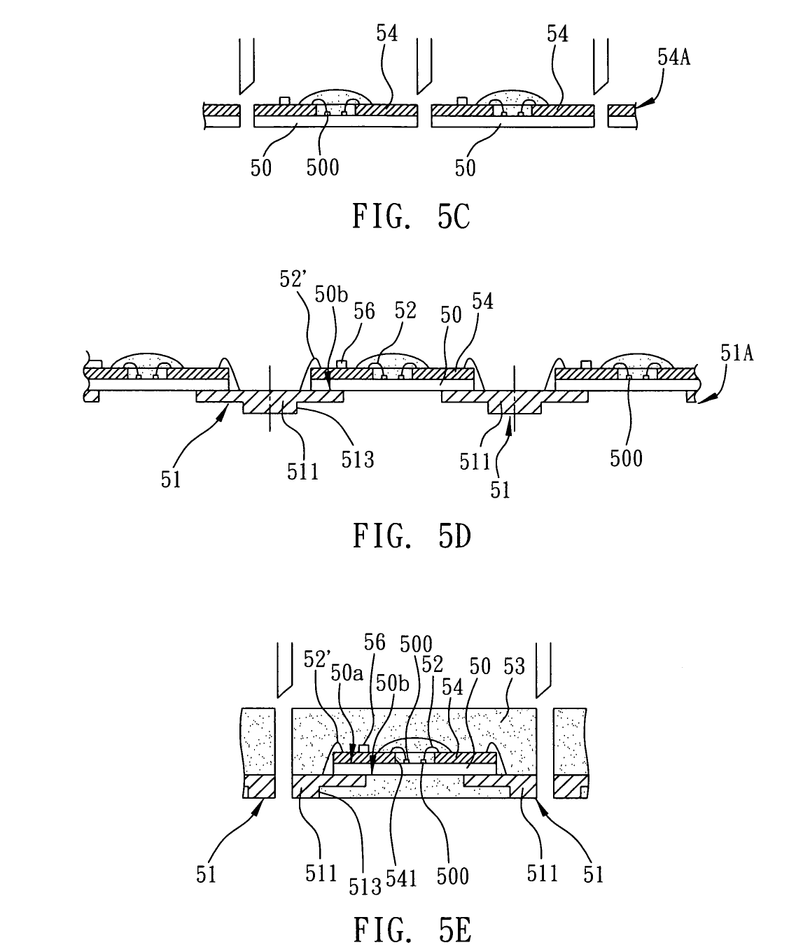

Referring to FIGS. 5A to 5E, the schematic cross-sectional views of the semiconductor package of the invention and the fabricating method thereof are shown.

The first embodiment of the invention is carried out in batches, so as to increase fabrication yield, however it can also be carried out as a single fabrication.

As shown in FIG. 5A, a substrate module 54A having a plurality of substrates 54 is provided. Each of the substrates 54 has at least one opening 541 and the shape of the opening 541 is based on the arrangement of bond pads disposed on the active surface of the semiconductor chip to be attached with the substrate. In the present embodiment, the bond pads on the active surface of the semiconductor chip are arranged in an I-shape, so the corresponding opening 541 is an I-shaped opening. In addition, a plurality of electrical connection pads 542 and conductive circuits 543 are formed on the substrate surface 54 for acting as electrical connections for the semiconductor chip 50. A plurality of bonding pads 545 are provided on the substrate 54 for passive components, such as resistors and capacitors to be attached thereon.

As shown in FIG. 5B, a semiconductor 50 having an active surface 50a and an opposing non-active surface 50b is attached to the substrate 54 in a manner that the active surface 50a is attached to the substrate 54. A plurality of bond pads 500 arranged in I-shape are disposed on the active surface 50a of the semiconductor chip 50 at positions corresponding to the I-shaped opening 541, allowing the bond pads 500 to be exposed. Bonding wires 52 are provided to pass through the opening 541 of the substrate 54 to electrically connect the bond pads 500 of the semiconductor chip 50 to the electrical connection pads 542 of the substrate 54. Moreover, an insulative material 55 is filled within the opening 541 of the substrate 54 so as to cover the bonding wires 52. In addition, the substrate 54 has at least one pair of passive component bond pads 545 formed thereon allowing at least one passive component 56 to be attached thereon, so as to increase the electrical functionality.

As shown in FIG. 5C, a singulation process is performed on the substrate module 54A to single out each of the semiconductor chips 50 each coupled with a substrate 54. In the present embodiment, the substrate 54 is substantially equal to the semiconductor chip 50 in size.

As shown in FIG. 5D, a leadframe module 51A having a plurality of leadframes 51 is provided. Each of the leadframe 51 has a plurality of leads 511, and the bottom surface of the inner portion of each of the leads 511 is formed with an indented structure 513. As shown in FIG. 5E, a molding process is performed to form an encapsulant 53 for encapsulating the substrate 54, semiconductor chip 50, bonding wires 52′ and the leadframe 51, allowing at least the bottom surface of the leads 511 of the leadframe 51 to be exposed from the encapsulant 53. The indented structure 513 formed on the bottom surface of the inner portion of the leads 511 of the leadframe 51 allows the leads 511 to be more effectively and firmly engaged with the encapsulant 53. Then, a singulation or punch process is performed to singulate each leadframe 51, so as to form a single semiconductor package of the present invention.

Accordingly, as shown in FIG. 5E, the semiconductor package of the invention comprises a semiconductor chip 50 having an active surface 50a, whereon a plurality of bond pads 500 are formed, and an opposing non-active surface 50b; a substrate 54 physically coupled with the active surface 50a of the semiconductor chip 50, having an opening 541 for exposing the bond pads 500; bonding wires 52 passing through the opening 541 for electrically connecting the bond pads 500 and the substrate 54; a leadframe 51 for supporting and electrically connecting the semiconductor chip 50 coupled with the substrate 54, wherein the leadframe 51 has a plurality of leads 511, and the bottom surface of an inner portion of each of the leads 511 is formed with an indented structure 513; bonding wires 52′ for electrically connecting the substrate 54 and the leads 511 of the leadframe 51; and an encapsulant 53 for encapsulating the semiconductor chip 50, substrate 54, and the leadframe 51, allowing at least the bottom surface of the lead 511 to be exposed from the encapsulant 53. Moreover, passive components can be attached on the substrate 54 in the semiconductor package, for improving the overall electrical functionality and performance of the package.

In accordance with the semiconductor package structure of the invention and the fabricating method thereof, an opening is formed in advance on the substrate based on the arrangement of the bonding pads, so that when the active surface of the semiconductor chip is attached to the substrate, the bond pads disposed on the active surface are exposed from the opening, allowing the bond pads of the semiconductor package to be electrically connected to the substrate via bonding wires. Subsequently, the semiconductor chip that is coupled to the substrate is attached and electrically connected (also via bonding wires) to a leadframe having a plurality of leads. Then, an encapsulant is formed to encapsulate the substrate, semiconductor chip, and the leadframe, in such a way that the bottom surfaces of the leads are exposed from the encapsulant so as to allow the package to be electrically connected to an external device, such that, a thin and compact package without extended lead is formed that can be used in packaging various semiconductor chips having differing arrangements of bond pads.

### Second Preferred Embodiment

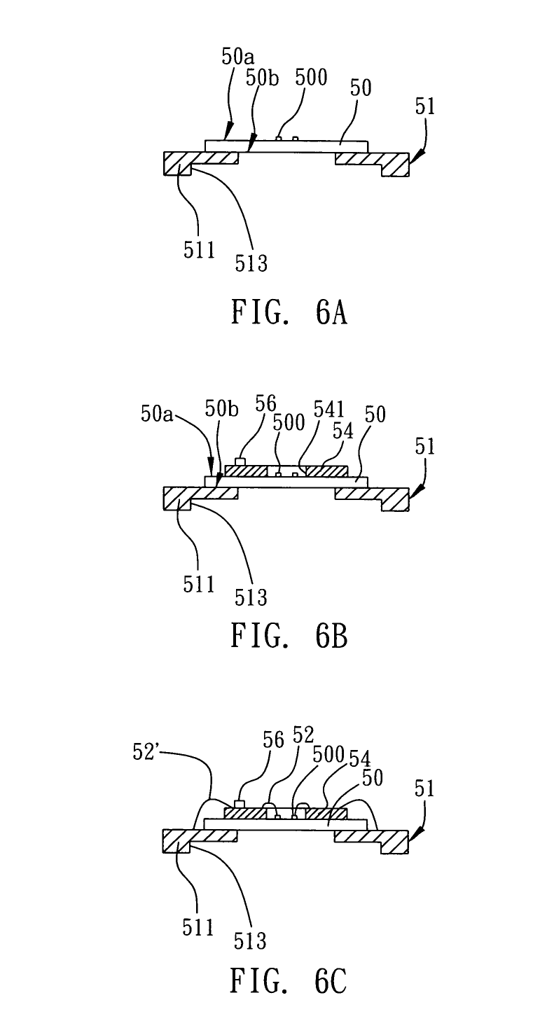

Referring to FIGS. 6A to 6D, cross-sectional views of the semiconductor package and the fabricating method thereof of the second preferred embodiment of the present invention are shown.

As shown in FIG. 6A, a leadframe 51 having a plurality of leads 511 is provided. Each lead 511 has an indented structure 513 formed on the bottom surface of the inner portion thereof to attach the semiconductor chip 50 on the leads 511. The semiconductor chip 50 has an active surface 50a and an opposing non-active surface 50b, and is attached to the leadframe 51 via the non-active surface 50b. A plurality of bond pads 500 is disposed on the active surface 50a of the semiconductor chip 50.

As shown in FIG. 6B, the active surface 50a of the semiconductor chip is attached to a substrate 54. The substrate 54 has an opening 541 at a position based on the arrangement of the bond pads 500 disposed on the active surface 50a of the semiconductor chip 50, allowing the bond pads 500 to be exposed from the opening 541. In addition, passive components 56 can be also attached on the substrate 54. The size of the substrate 54 can be larger than, equal to, or smaller than the size of the semiconductor chip 50.

As shown in FIG. 6C, bonding wires 52 are used to electrically connect the bond pads 500 of the semiconductor chip 50 to the substrate 54, and bonding wires 52′ are used to electrically connect the leadframe 51 to the substrate 54.

As shown in FIG. 6D, an encapsulant 53 is formed for encapsulating the substrate 54, semiconductor chip 50, bonding wires 52, 52′ and the leadframe 51, wherein at least the bottom surfaces of the leads 511 of the leadframe 51 are left exposed from the encapsulant 53.

In the present embodiment, wire bonding between the substrate and the leadframe can be implemented immediately after wire bonding between the bond pads of the semiconductor chip and the substrate (i.e., during the same process), eliminating the step of filling the substrate opening with an insulative material, thereby facilitating the fabricating process.

### Third Preferred Embodiment

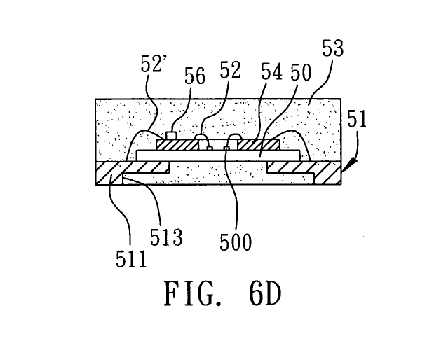

As shown in FIG. 7, a cross-sectional view of the semiconductor package of the third preferred embodiment of the invention is shown.

The third preferred embodiment of the invention is almost the same as the forgoing first preferred embodiment. The major difference is that in the present embodiment, the size of the substrate 54 is larger than the size of the semiconductor chip 50, allowing the semiconductor chip 50 to be attached to the inner portion 511a of the leads 511, while the substrate 54 attached on the semiconductor chip 50 is electrically connected to the leads 511.

### Fourth Preferred Embodiment

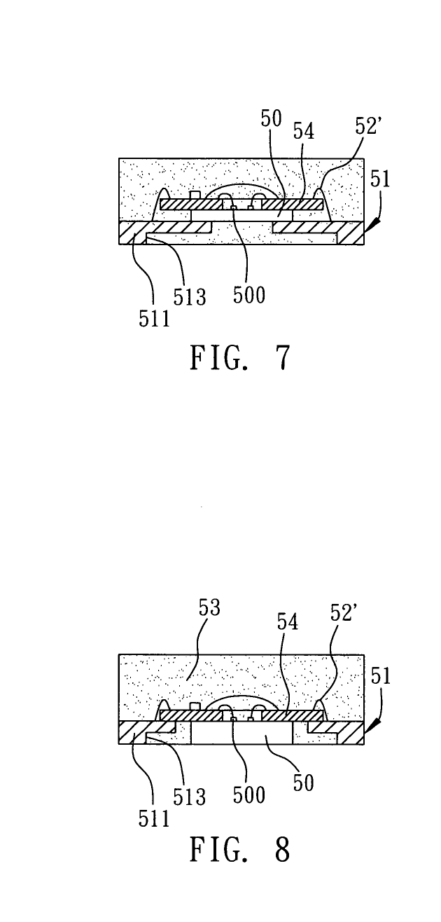

Referring to FIG. 8, a cross-sectional view of the semiconductor package of the fourth preferred embodiment of the invention is shown.

The fourth preferred embodiment of the invention is almost the same as the foregoing first preferred embodiment. The major difference is that in the present embodiment, the size of the substrate 54 is larger than the size of the semiconductor chip 50, allowing the substrate 54 to be attached and electrically connected to the inner portion 511a of the leads 511 of the lead frame 51 via bonding wires 52′, as well as allowing the semiconductor chip 50 to be accommodated between the two inner portions 511a of the leads 511. Moreover, the non-active surface of the semiconductor chip 50 is exposed from the encapsulant, so as to increase heat-dissipating efficiency.

### Fifth Preferred Embodiment

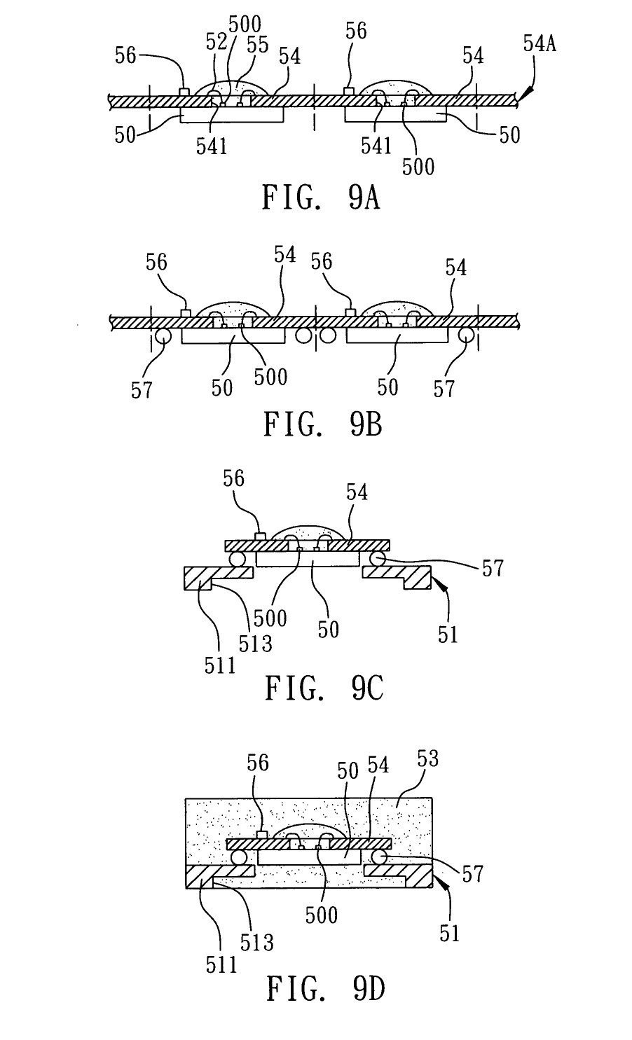

Refereeing to FIGS. 9A to 9D, cross-sectional views of the semiconductor package of the fifth preferred embodiment of the invention and the fabricating method thereof are shown.

The fifth preferred embodiment of the invention is almost the same as the foregoing fourth preferred embodiment. The major difference is that the substrate is electrically connected to the leads directly via conductive materials, and the semiconductor chip is accommodated between the leads.

As shown in FIG. 9A, a substrate module 54A having a plurality of substrates 54 is provided for a semiconductor chip 50 to be attached on each substrate 54. Each substrate 54 has at least one opening 541 for exposing the corresponding bond pads 500 on the active surface of the semiconductor chip 50, wherein bonding wires 52 are used to electrically connect the bond pads 500 of the semiconductor chip to the top surface of the substrate 54. Then, the opening 541 is filled with an insulative material 55 for encapsulating the bonding wires 52. Meanwhile, at least one passive component 56 is attached and electrically connected to the top surface of the substrate 54, so as to improve the electronic functionality or performance of the package.

As shown in FIG. 9B, on the bottom surface of the substrate 54, a plurality of conductive components such as solder balls 57 are formed.

As shown in FIG. 9C, a singulation process is performed to singulate out each substrate, and a leadframe 51 having a plurality of leads 511 is provided, each of which is formed with an indented structure on the bottom surface of the inner portions thereof, so as to effectively engage the semiconductor chip 50 that is coupled with a substrate 54 to the leadframe 51, allowing the substrate to be electrically connected to the leads 511 of the leadframe 51 via the solder balls 57.

As shown in FIG. 9D, a molding process is performed to form an encapsulant 53 for encapsulating the semiconductor chip 50, substrate, and the leadframe 51, in such a way that at least the bottom surfaces of the leads 511 are exposed from the encapsulant 53.

### Sixth Preferred Embodiment

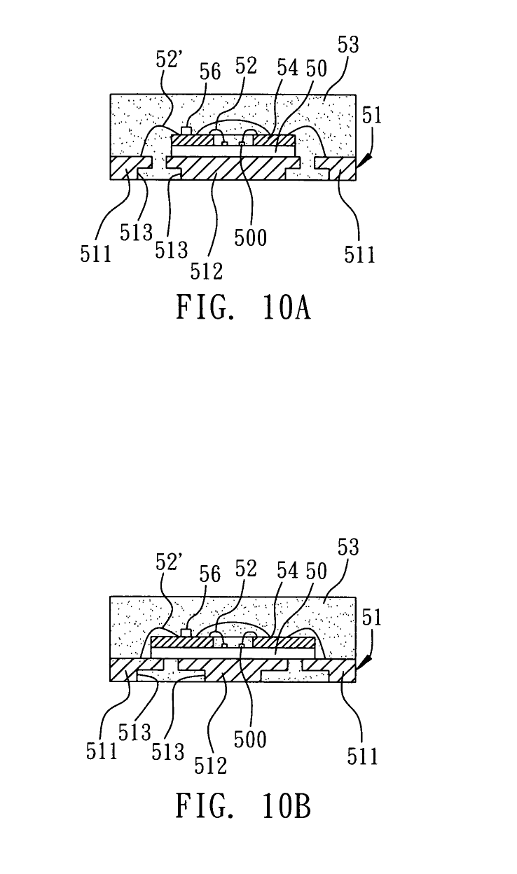

Referring to FIGS. 10A and 10B, cross-sectional views of the sixth preferred embodiment of the semiconductor package of the invention are shown.

The sixth preferred embodiment of the invention is almost the same as the foregoing first preferred embodiment. The major difference is that the leadframe 51 comprises a die pad 512 and leads 511 formed on two opposing sides of the die pad 512, allowing a semiconductor chip 50 that is coupled to a substrate 54 to be directly attached to the die pad 512 (as shown in FIG. 10A), or attached to the die pad 512 and the leads 511 (as shown in FIG. 10B). The bottom surfaces of the die pad 512 and the leads 511 are exposed from an encapsulant 53 to provide good support and efficient heat dissipation for the semiconductor chip 50 attached on the die pad 512. Indented structures 513 are formed on two sides of the die pad 512 and the leads 511 adjacent to the die pad 512 so as to increase the bonding force between the leadframe 51 and the encapsulant 53. The size of the substrate attached on the semiconductor chip can be larger than, smaller than, or equal to the size of the semiconductor chip.

### Seventh Preferred Embodiment

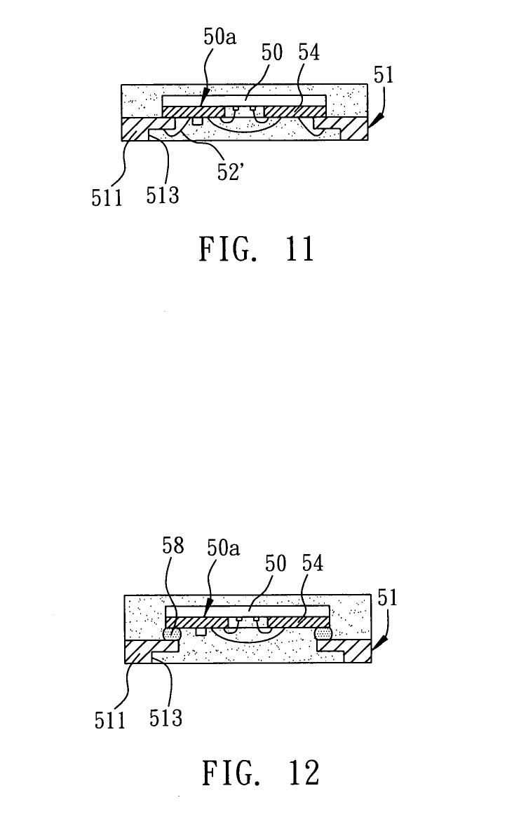

Referring to FIG. 11, a cross-sectional view of the semiconductor package of the seventh preferred embodiment of the invention is shown.

The seventh preferred embodiment is almost the same as the foregoing first preferred embodiment. The major difference is that in the present embodiment, the semiconductor chip 50 that has a substrate attached on the active surface thereof is turned upside down so that one side of the substrate 54 is attached to the leads 511 and bonding wires 52 are used to electrically connected the substrate 54 to the indented structure 513 of the leads 511.

### Eighth Preferred Embodiment

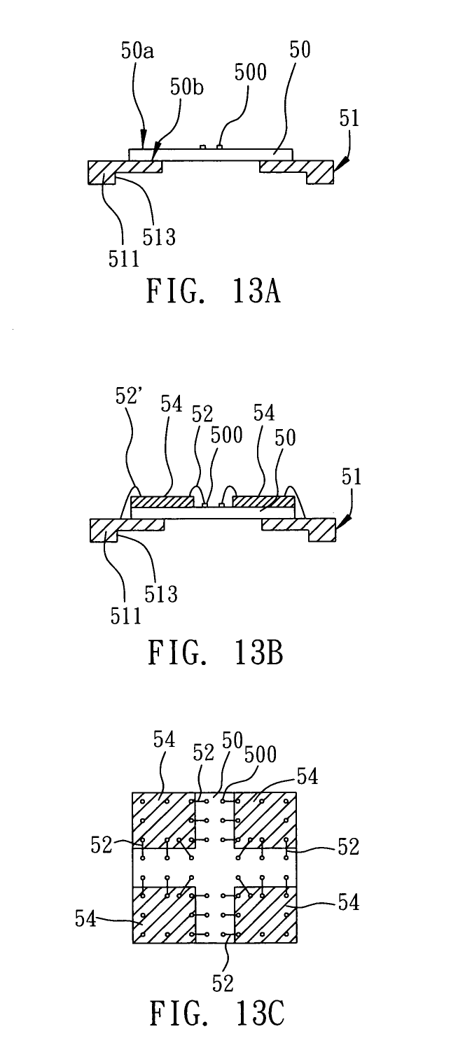

Referring to FIG.12, a cross-sectional view of the semiconductor package of the eighth preferred embodiment of the invention is shown.

The eighth preferred embodiment is almost the same as the foregoing first preferred embodiment. The major difference is that in the present embodiment, the semiconductor chip 50 that has a substrate attached on the active surface thereof is turned upside down so that one side of the substrate 54 is attached to the leads 511 and is electrically connected directly to the leads 511 via conductive material 58 such as solder balls or conductive adhesive.

### Ninth Preferred Embodiment

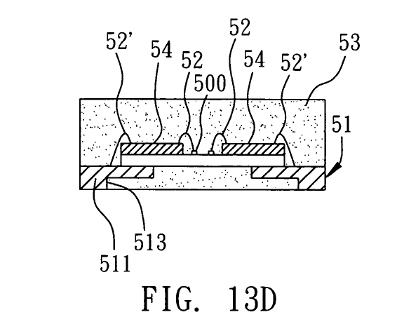

Referring to FIGS. 13A to 13D, cross-sectional views of the semiconductor package of the ninth preferred embodiment of the invention and the fabricating method thereof are shown.

The ninth preferred embodiment is almost the same as the foregoing second preferred embodiment. The major difference is that in the present embodiment a plurality of substrates are disposed on the active surface of the semiconductor chip in such a way that the bond pads on the active surface of the semiconductor chip are exposed for electrically connecting the bond pads of the semiconductor chip to the substrate.

As shown in FIG. 13A, a semiconductor chip having an active surface 50a and an opposing non-active surface 50b is attached to the leadframe 51 having a plurality of leads 511. An indented structure 513 is formed on the bottom surface of the inner portion of each lead 511 and a plurality of bond pads 500 are disposed on the active surface 50a of the semiconductor chip 50 and the semiconductor chip 50 is attached to the leadframe 51 via its non-active surface 50b.

As shown in FIG. 13B, a plurality of substrates 54 is disposed on the semiconductor chip 50 at positions such that the bond pads 500 on the active surface 50a of the semiconductor chip 50 are exposed. Through a wire bonding process, bonding wires 52, 52′ are used to electrically connect the bond pads 500 on the semiconductor chip 50 to the substrate 54 and electrically connect the substrate 54 to the leadframe 51, respectively. Moreover, FIG. 13C shows a planar view at the situation where substrates 54 have been disposed on the semiconductor chip 50 and are in the process of wire bonding. Only four substrates 54 are shown disposed on the semiconductor chip 50 in this figure; however, the scope of the invention is not limited to this number or configuration. On the contrary, the number can be varied according to the practical electrical requirements and the bond pad arrangement.

As shown in FIG. 13D, a molding process is performed to form an encapsulant 53 which encapsulates the semiconductor chip 50, substrate 54, bonding wires 52, 52′ and the leadframe 51, allowing the bottom surface of the leads 511 of the leadframe 51 to be exposed from the encapsulant 53.

Certainly in the fabricating method of the present embodiment, it is also feasible to attach the substrate to the semiconductor chip prior to attaching the semiconductor chip that is coupled to the substrate. It should be noted that, in practice, many variations and differences between the above embodiments could be combined together.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package, comprising:
a semiconductor chip having an active surface, a non-active surface opposing to the active surface, and a plurality of bond pads formed on the active surface;
a substrate attached on the active surface of the semiconductor chip where the bond pads are exposed;
a plurality of bonding wires electrically connecting the bond pads of the semiconductor chip with the substrate;
a leadframe having a plurality of leads, providing physical support for and electrically connected with the semiconductor chip coupled with the substrate; and
an encapsulant for encapsulating the semiconductor chip, substrate, and leadframe, except where bottom surfaces of the leads of the leadframe are exposed.

2. The semiconductor package of claim 1, wherein the substrate is larger in size than the semiconductor chip to allow the substrate to be attached on the leads and to allow the semiconductor chip to be accommodated between two rows of opposing leads.

3. The semiconductor package of claim 1, wherein the non-active surface of the semiconductor chip is exposed to the encapsulant.

4. The semiconductor package of claim 1, further comprising at least one passive component attached on the substrate.

5. The semiconductor package of claim 1, wherein the substrate attached on the semiconductor chip has at least one opening for exposing the bond pads on the active surface of the chip.

6. The semiconductor package of claim 5, wherein the shape of the opening is based on the arrangement of the bond pads disposed on the active surface of the semiconductor chip.

7. The semiconductor package of claim 1, further comprising an insulative material for covering the bonding wires that are used to electrically connect the semiconductor chip and the substrate.

8. The semiconductor package of claim 1, wherein there is more than one substrate and such substrates are arranged in a way that the bond pads are exposed.

9. The semiconductor package of claim 1, wherein the size of the substrate can be larger than, smaller than, or equal in size to the semiconductor chip.

10. The semiconductor package of claim 1, wherein the leadframe comprises a die pad for attaching a semiconductor chip thereon and leads adjacent to the die pad.

11. The semiconductor package of claim 10, wherein the bottom surface of the die pad is exposed from the encapsulant.

12. The semiconductor package of claim 10, wherein the die pad and the bottom surface of the leads adjacent to the die pad are formed with indented structures.

13. The semiconductor package of claim 1, wherein the semiconductor chip coupled with the substrate is attached to the leads via either the substrate or the semiconductor chip, and is electrically connected to the leads via the bonding wires or conductive materials.

14. The semiconductor package of claim 1, wherein the semiconductor chip coupled with the substrate is attached to the leads via one side of the substrate in an upside down manner and the substrate is electrically connected to the leads via conductive materials or electrically connected to the indented structures of the leads via the bonding wires.

15. A fabricating method for a semiconductor package, comprising:
providing a semiconductor chip having an active surface whereon a plurality of bond pads are formed and an opposing non-active surface, which is attached to a substrate via its active surface in such a way that the bond pads are exposed for electrically connecting with various points on the substrate;
attaching and electrically connecting the semiconductor chip coupled with the substrate to a leadframe having a plurality of leads;
forming an encapsulant for encapsulating the semiconductor chip, substrate, and leadframe in such a way that at least the bottom surfaces of the leads are exposed from the leadframe, wherein an indented structure is formed on the bottom surface of the inner portion of each lead, for firmly engaging the leads with the encapsulant.

16. The fabricating method for a semiconductor package of claim 15, wherein the size of the substrate is larger than the semiconductor chip to allow the substrate to be attached on the leads and to allow the semiconductor chip to be accommodated between the two rows of opposing leads.

17. The fabricating method for a semiconductor package of claim 16, wherein the non-active surface of the semiconductor chip is exposed to the encapsulant.

18. The fabricating method for a semiconductor package of claim 15, further comprising at least one passive component attached on the substrate.

19. The fabricating method for a semiconductor package of claim 15, wherein the substrate attached on the semiconductor chip has at least one opening for exposing the bond pads on the active surface of the chip.

20. The fabricating method for a semiconductor package of claim 19, wherein the shape of the opening is based on the arrangement of bond pads disposed on the active surface of the semiconductor chip.

21. The fabricating method for a semiconductor package of claim 15, wherein there is more than one substrate, and the substrates are arranged in such a way that the bond pads are exposed.

22. The fabricating method for a semiconductor package of claim 15, wherein the size of the substrate can be larger than, equal to, or smaller than the semiconductor chip.

23. The fabricating method for a semiconductor package of claim 15, wherein the leadframe comprises a die pad for attaching a semiconductor chip thereon and leads adjacent to the die pad.

24. The fabricating method for a semiconductor package of claim 23, wherein the bottom surface of the die pad is exposed from the encapsulant.

25. The fabricating method for a semiconductor package of claim 23, wherein the die pad and the bottom surface of the leads adjacent to the die pad are formed with indented structures.

26. The fabricating method for a semiconductor package of claim 15, wherein the semiconductor chip coupled with the substrate is attached to the leads via either the substrate or the semiconductor chip, and is electrically connected to the leads via the bonding wires or conductive materials.

27. The fabricating method for a semiconductor package of claim 15, wherein the semiconductor chip coupled with the substrate is attached to the leads via one side of the substrate in an upside down manner, and the substrate is electrically connected to the leads via conductive materials or electrically connected to the indented structures of the leads via the bonding wires.

28. The fabricating method for a semiconductor package of claim 15, wherein the bond pads of the semiconductor chip are electrically connected to the substrate via bonding wires which can be covered by an insulative material.

29. The fabricating method for a semiconductor package of claim 15, wherein forming electrical connection between the substrate and the semiconductor chip and between the substrate and the leadframe is achieved through wire bonding during the same process.

30. A fabricating method for a semiconductor package, comprising:
attaching a semiconductor chip having an active surface and an non-active surface to a leadframe having a plurality of leads wherein the active surface of the semiconductor chip is disposed with a plurality of bond pads and the semiconductor chip is attached to the leadframe via its non-active surface;
disposing substrates on the active surface of the semiconductor chip, wherein the bond pads are exposed;
electrically connecting the substrate to the semiconductor chip and electrically connecting the substrate to the leadframe; and
forming an encapsulant for encapsulating the semiconductor chip, substrate, and leadframe in such a way that at least the bottom surfaces of the leads are exposed from the leadframe, wherein an indented structure is formed on the bottom surface of the inner portion of each lead, for firmly engaging the leads with the encapsulant.

31. The fabricating method for a semiconductor package of claim 30, wherein the size of the substrate is larger than the semiconductor chip to allow the substrate to be attached on the leads and to allow the semiconductor chip to be accommodated between the two rows of opposing leads.

32. The fabricating method for a semiconductor package of claim 31, wherein the non-active surface of the semiconductor chip is exposed to the encapsulant.

33. The fabricating method for a semiconductor package of claim 30, further comprising at least one passive component attached on the substrate.

34. The fabricating method for a semiconductor package of claim 30, wherein the substrate attached on the semiconductor chip has at least one opening for exposing the bond pads on the active surface of the chip.

35. The fabricating method for a semiconductor package of claim 34, wherein the shape of the opening is based on the arrangement of bond pads disposed on the active surface of the semiconductor chip.

36. The fabricating method for a semiconductor package of claim 30, wherein there is more than one substrate and the substrates are arranged in a way that the bond pads are exposed.

37. The fabricating method for a semiconductor package of claim 30, wherein the size of the substrate can be larger than, equal to, or smaller than the semiconductor chip.

38. The fabricating method for a semiconductor package of claim 30, wherein the leadframe comprises a die pad for attaching a semiconductor chip thereon and leads adjacent to the die pad.

39. The fabricating method for a semiconductor package of claim 38, wherein the bottom surface of the die pad is exposed from the encapsulant.

40. The fabricating method for a semiconductor package of claim 38, wherein the die pad and the bottom surface of the leads adjacent to the die pad are formed with indented structures.

41. The fabricating method for a semiconductor package of claim 30, wherein the substrate is electrically connected to the leads via the bonding wires and conductive materials.

42. The fabricating method for a semiconductor package of claim 30, wherein the bond pads of the semiconductor chip are electrically connected to the substrate via bonding wires which can be covered by an insulative material.

43. The fabricating method for a semiconductor package of claim 15, wherein forming electrical connection between the substrate and the semiconductor chip and between the substrate and the leadframe is achieved through wire bonding during the same process.
